(19) United States
(12) Patent Application Publication
(10) Pub. No.: US 2013/0078784 A1
(43) Pub. Date: Mar. 28, 2013

(54) CMP SLURRY AND METHOD FOR MANUFACTURING SEMICONDUCTOR DEVICE

(71) Applicants: Gaku MINAMIHABA, Yokohama-shi (JP); Akifumi Gawase, Yokohama-shi (JP); Yukiteru Matsui, Yokohama-shi (JP); Hajime Eda, Yokohama-shi (JP)

(72) Inventors: Gaku MINAMIHABA, Yokohama-shi (JP); Akifumi Gawase, Yokohama-shi (JP); Yukiteru Matsui, Yokohama-shi (JP); Hajime Eda, Yokohama-shi (JP)

(21) Appl. No.: 13/425,979

(22) Filed: Mar. 21, 2012

(30) Foreign Application Priority Data
Sep. 27, 2011 (JP) 2011-211001

(51) Int. Cl. H01L 21/762; C09K 13/00

(52) U.S. Cl. 438/430; 438/435; 252/79.1; 257/E21.547; 257/E21.546

(57) ABSTRACT

According to one embodiment, the CMP slurry includes abrasive particles made of colloidal silica in an amount of 0.5 to 3% by mass of a total mass of the CMP slurry, and a polycarboxylic acid having a weight average molecular weight of from 500 to 10,000, in an amount of 0.1 to 1% by mass of the total mass of the CMP slurry. 50 to 90% by mass of the abrasive particles each has a primary particle diameter of 3 to 10 nm. The CMP slurry has a pH within a range of 2.5 to 4.5.

### CROSS-REFERENCE TO RELATED APPLICATIONS

This application is based upon and claims the benefit of priority from prior Japanese Patent Application No. 2011-211001, filed Sep. 27, 2011, the entire contents of which are incorporated herein by reference.

### FIELD

Embodiments described herein relate generally to a CMP slurry and a method for manufacturing a semiconductor device.

### BACKGROUND

Currently, chemical mechanical polishing (CMP) using a ceria-based slurry is adopted to the formation of shallow trench isolation (STI) for element isolation in the manufacture of semiconductor devices. STI is formed by providing a groove to a semiconductor substrate comprising a CMP stopper film, forming a silicon oxide film thereon, and removing the excess silicon oxide film by CMP.

The ceria-based slurry has a high polishing rate against a silicon oxide film but has a low polishing rate against a CMP stopper film. The ceria-based slurry is advantageous in that it can polish a silicon oxide film with a high selectivity could have not been achieved by a silica-based slurry.

Reduction of use of rare earth elements is desired, but a slurry having performances that are even equal to that of the ceria-based slurry could have not been obtained yet at present.

### BRIEF DESCRIPTION OF THE DRAWINGS

FIGS. 1A, 1B and 1C are cross-sectional views illustrating the steps of manufacturing STI;

FIG. 2 is a drawing explaining the method for manufacturing a semiconductor device of according to one embodiment; and

FIGS. 3A, 3B and 3C are cross-sectional views explaining the steps of manufacturing a plug.

### DETAILED DESCRIPTION

In general, according to one embodiment, the CMP slurry comprises abrasive particles made of colloidal silica in an amount of 0.5 to 3% by mass of a total mass of the CMP slurry; and a polycarboxylic acid having a weight average molecular weight of from 500 to 10,000, in an amount of 0.1 to 1% by mass of the total mass of the CMP slurry. 50 to 90% by mass of the abrasive particles each has a primary particle diameter of from 3 to 10 nm. The CMP slurry has a pH within a range of 2.5 to 4.5.

Embodiments will be hereinafter described.

The CMP slurry of the present embodiment includes colloidal silica as abrasive particles, and the amount thereof is defined to be from 0.5 to 3% by mass of the total mass of the slurry. When the amount of the colloidal silica is too small, the silicon oxide film cannot be polished at a practical rate (180 nm/min or more). On the other hand, a slurry comprising excessive colloidal silica cannot selectively polish the silicon oxide film,.and also polishes the lower layer thereof, a CMP stopper film. The CMP stopper film as a lower layer of the silicon oxide film is generally constituted by a silicon nitride film or a polysilicon film.

In the case when the CMP stopper film is polished together with the silicon oxide film, the planarity of the surface after the polishing is also decreased. Therefore, in the CMP slurry of the embodiment, the amount of colloidal silica has been defined to 0.5 to 3% by mass of the total mass of the slurry. The amount of colloidal silica is preferably 1 to 2% by mass of the total mass of the slurry.

Each of the particles of 50 to 90% by mass of the entirety of the colloidal silica has a primary particle diameter of 3 to 10 nm. The primary particle diameter of the colloidal silica Can be obtained by the following means.

First, a TEM image (magnification: 500,000 to 1,000,000 times) of the colloidal silica is obtained, and 200 particles are selected randomly from the image. For each particle, the peripheral length is approximated by a circle, and the diameter thereof is defined as a primary particle diameter. Specifically, the peripheral length is approximated by a circle using general image analysis software. The case when 100 to 180 particles each having a primary particle diameter of 3 to 10 nm are present falls within the scope of the embodiment.

In the case when particles each having a primary particle diameter of 3 to 10 nm are too little, the planarity of the surface after the polishing is decreased. Furthermore, the polishing rate of the CMP stopper film is increased, and thus a desired selectivity cannot be obtained. In the case when particles each having a primary particle diameter of 3 to 10 nm are too much, the polishing rate of the CMP stopper film is further increased, and thus the selectivity and planarity are decreased significantly.

In the case when the particles of 50% by mass or more of the total mass of silica each has a primary particle diameter of less than 3 nm, the silicon oxide film cannot be polished at a practical rate. On the other hand, in the case when 50% by mass or more of the total mass of silica has a primary particle diameter of more than 10 nm, the polishing rate of the CMP stopper film is increased significantly and thus the selectivity cannot be ensured.

In order to polish the silicon oxide film selectivity with a practical rate without substantially polishing the CMP stopper film, the primary particle diameter of 50 to 90% by mass of the total mass of silica is defined to 3 to 10 nm. In the case when the polishing rate is less than 10 nm/min, it can be considered that polishing is not substantially conducted. The silica as mentioned below can control the amount of silica having a primary particle diameter of 3 to 10 nm to 50 to 90% by mass of the total mass of silica. Examples include colloidal silica such as a silica generated by hydrolysis of an alkoxysilane and a silica formed by removing sodium from an aqueous solution of sodium silicate.

As long as the particles each having a primary particle diameter of 3 to 10 nm account for 50 to 90% by mass of the total mass of silica, the primary particle diameter of the silica in the rest is not specifically limited. There is no problem if a silica having a primary particle diameter of more than 50 nm is included by about 1% by mass of the total mass of silica. A silica having a primary particle diameter of less than 3 nm may be included up to about 10% by mass of the total mass of silica.

The CMP slurry of the embodiment includes a polycarboxylic acid having a weight average molecular weight of 500 to 10,000 at a predetermined amount besides the colloidal silica as abrasive particles. The polycarboxylic acid assists in the formation of an aggregate of the silica. When the weight average molecular weight of the polycarboxylic acid is too small, the planarity of the surface after the polishing is decreased. When the weight average molecular weight of the polycarboxylic acid is too high, the silicon oxide film cannot be polished at a practical rate. Therefore, the weight average molecular weight of the polycarboxylic acid has been defined to 500 to 10,000. The weight average molecular weight of the polycarboxylic acid is preferably 1,000 to 6,000.

For example, a weight average molecular weight (Mw) in polyethylene glycol equivalent measured by gel permeation chromatography (GPC) can be applied to the weight average molecular weight of the polycarboxylic acid.

When the amount of the polycarboxylic acid is too little, the planarity of the surface after the polishing is decreased, whereas when the amount of the polycarboxylic acid is too much, the silicon oxide film cannot be polished at a practical rate. Therefore, the amount of the polycarboxylic acid is defined to 0.1 to 1% by mass of the total mass of the slurry. The amount of the polycarboxylic acid is preferably 0.3 to 0.6% by mass of the total mass of the slurry.

Examples of the polycarboxylic acid may include a polyacrylic acid, a polymethacrylic acid, a polymaleic acid and salts thereof, and the like. A polyacrylic acid is specifically preferable since it is excellent in molecular weight controllability and has fine hydrophilic-hydrophobic balance at a weight average molecular weight of 500 to 10,000. An aggregate of the silica is suitably formed and interaction with a polishing cloth is sufficiently increased, thereby enabling high-speed polishing.

Furthermore, the pH is defined to be within the range of 2.5 to 4.5 in the CMP slurry of the embodiment. When the pH is less than 2.5, the polishing rate of the CMP stopper film made of the silicon nitride film or the like is increased, and thus the selectivity cannot be ensured. On the other hand, when the pH is more than 4.5, the polishing rate of the CMP stopper film is increased, and the silicon oxide film cannot be polished at a practical rate. Therefore, the selectivity is decreased significantly, and the planarity after the polishing is also decreased.

By adding a pH adjusting agent such as maleic acid, citric acid, malic acid, oxalic acid and malonic acid, the pH can be adjusted to an intended pH. The CMP slurry of the embodiment preferably has a pH in the range of 3 to 3.5.

By having all of the above conditions, it became possible to obtain a CMP slurry that can polish a silicon oxide film at a high speed without substantially polishing a CMP stopper film such as a silicon nitride film.

The CMP slurry of the embodiment can be obtained by adding predetermined colloidal silica and a polycarboxylic acid to water. As the water, for example, pure water can be used.

Where necessary, additives such as a nonionic surfactant such as polyvinyl alcohol, polyoxyethylene and polyvinyl pyrrolidone may be included in the CMP slurry of the embodiment. Such additive can be added by an amount of from about 0.01 to about 0.5% by mass of the total mass of the slurry in the case when enhancement of planarity and decrease of scratch are intended.

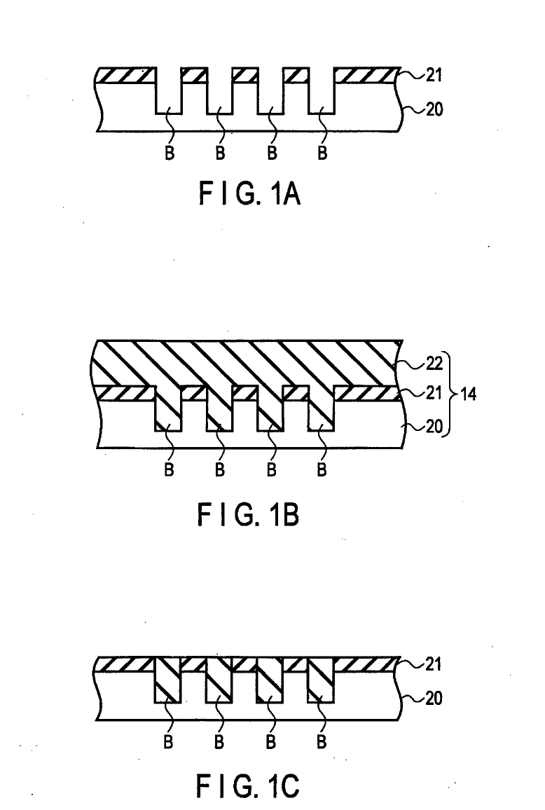

The CMP slurry of the embodiment can be applied to the manufacture of STI. The method for manufacturing STI will be explained with reference to FIGS. 1A to 1C. First, a semiconductor substrate 20 comprising a CMP stopper film 21 on the surface thereof, to which STI patterns B are provided, as shown in FIG. 1A, is prepared. As the CMP stopper film 21, a silicon nitride film or a polysilicon film can be used.

A silicon oxide film or the like, for example, may be provided between the semiconductor substrate 20 and the CMP stopper film 21. The silicon oxide film 20 is processed together with the CMP stopper film 21 using a silicon oxide film or the like as an etching mask, thereby forming the STI patterns B. The width and interval of the STI patterns B can be suitably determined in the range of 0.01 to 5 μm, and the depth of the STI patterns B can be suitably determined in the range of 100 to 1,000 nm.

As shown in FIG. 1B, a silicon oxide film 22 is formed on the CMP stopper film 21. For the formation of the silicon oxide film 22, for example, a high-density plasma CVD process (HDP-CVD) or the like can be adopted. The thickness of the silicon oxide film 22 can be suitably determined in the range of 150 to 1,100 nm, and the film is also formed outside of the STI patterns B throughout the whole surface. Since the silicon oxide film 22 becomes a film to be polished, the constitution illustrated in FIG. 1B can be referred to as a semiconductor substrate having a film to be polished 14.

Next, CMP of the whole surface is conducted to remove the silicon oxide film 22 outside of the STI pattern B as illustrated in FIG. 1C. The silicon oxide film 22 is embedded in the inside of the STI patterns B, and the surface of the CMP stopper film 21 is exposed outside of the STI patterns B.

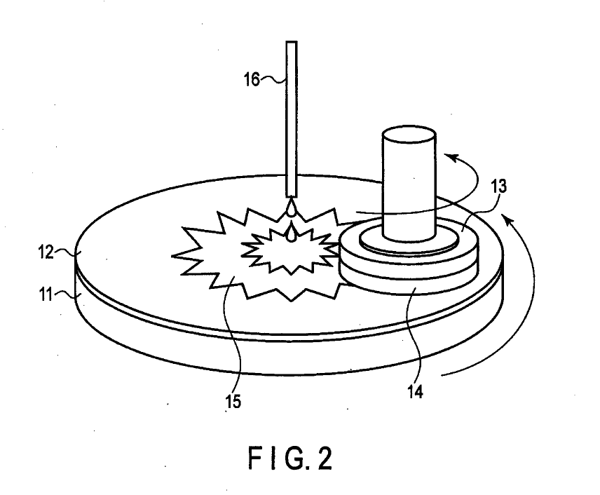

In the polishing of the silicon oxide film 22, as illustrated in FIG. 2, a polishing head 13 retaining a semiconductor substrate having a film to be polished 14 is contacted to a turntable 11 to which a polishing cloth 12 has been attached while the turntable 11 is rotated by a rotation mechanism (not depicted). As illustrated in FIG. 1B, a silicon oxide film as a film to be polished is formed in the semiconductor substrate having a film to be polished 14.

The polishing load can be suitably selected within the range of 100 to 500 hPa, and the rotation numbers of the turntable and polishing head can be suitably selected within the range of 30 to 120 rpm. A sample as a slurry 15 is fed from a slurry feeding nozzle 16 to the central area of the polishing cloth 12, and polishing is conducted for a predetermined period, thereby remaining the silicon oxide film in the STI patterns B and obtaining STI as illustrated in FIG. 1C.

As mentioned above, the CMP slurry of the embodiment has a high polishing rate against a silicon oxide film but has a low polishing rate against a CMP stopper film such as a silicon nitride film and a polysilicon film. Such CMP stopper film is also provided to a lower layer such as a W film in the formation of a plug. In the case when an oxidizing agent is added to the CMP slurry of the embodiment, a metal film can be polished selectively with respect to the CMP stopper film.

Examples of the oxidizing agent may include hydrogen peroxide, diammonium persulfate and the like. The amount of the oxidizing agent may be from about 0.05 to about 5% by mass of the total mass of the slurry. The CMP slurry of the embodiment including the oxidizing agent can polish metal films of W, Ti, Mo, Ta, Cu and nitrides, oxides and carbides comprising these as a main component, and mixtures thereof, at a practical polishing rate (20 nm/min or more). Furthermore, the polishing rates of the silicon nitride film and polysilicon film are less than about 10 nm/min. Therefore, for example, a metal film provided on a silicon nitride film as a CMP stopper film can be polished with a high selectivity.

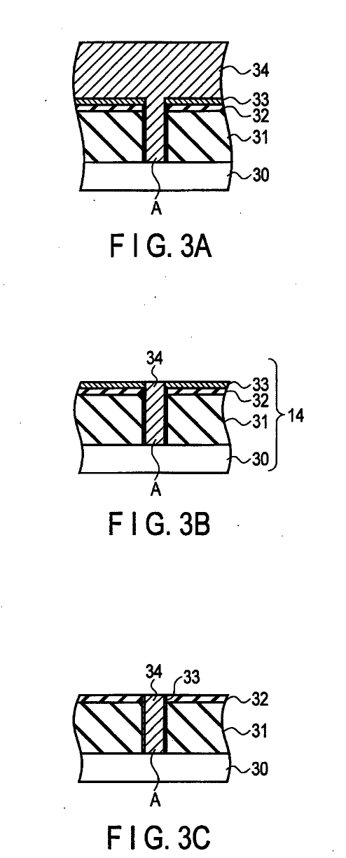

The formation of a fine plug will be explained with reference to FIGS. 3A to 3C. First, as illustrated in FIG. 3A, a hole A is formed on an insulating film 31 and a CMP stopper film 32 that are formed on a semiconductor substrate 30 in this order, and a barrier metal 33 and a wiring material film 34 are formed. A semiconductor element (not depicted) is formed on the semiconductor substrate 30.

The insulating film 31 can be, for example, a silicon oxide film having a thickness of 500 to 5,000 nm, and the CMP stopper film 32 formed thereon can be, for example, a silicon nitride film having a thickness of 10 to 50 nm. The hole A formed thereon can be, for example, a fine hole having a width of 30 to 100 nm and a surface coverage of 0.0001 to 65%. The surface coverage as used herein refers to a density of a hole at any area.

The barrier metal 33 can be formed on the whole surface by, for example, a CVD process or the like. This barrier metal 33 can be formed, for example, using Ti, TiN or the like by a thickness of 3 to 50 nm. The wiring material film 34 on the barrier. metal 33 is also formed on the whole surface in a similar manner by a CVD process or the like. The wiring material film 34 can be formed, for example, using W or the like at a thickness of 100 to 600 nm. As illustrated in FIG. 3A, the wiring material film 34 is also formed outside of the hole A.

Next, as illustrated in FIG. 3B, CMP of the whole surface is conducted to remove the wiring material film 34 outside of the hole A (first polish). The slurry as used for the CMP herein can be suitably selected according to the material of the wiring material film. The wiring material film 34 is embedded in the hole A by the first polish, and the surface of the barrier metal 33 is exposed outside of the hole A. Since the barrier metal 33 becomes a film to be polished, the constitution illustrated in FIG. 3B can be referred to as a semiconductor substrate comprising a film to be polished 14.

Thereafter touch-up CMP is conducted to remove the barrier metal 33 outside of the hole A, thereby exposing the surface of the CMP stopper film 32 as illustrated in FIG. 3C. At this time, a part of the surface of the CMP stopper film 32 is also removed. By this way, the wiring material film 34 is embedded through the barrier metal 33 in the hole A of the insulating film 31 having the CMP stopper film 32 on the surface thereof, thereby forming a plug.

Hereinafter the specific examples of the CMP slurry and the method for manufacturing a semiconductor device will be shown.

### EXAMPLE 1

A colloidal silica as abrasive particles and a polyacrylic acid were added to pure water to prepare a slurry of sample No. 1. The concentration of the colloidal silica was 1.5% by mass of the total mass of the slurry, and 60% by mass of the particles of the entirety of the colloidal silica each had a primary particle diameter of 3 m to 10 nm. As mentioned above, the primary particle diameter of the colloidal silica was obtained from an image of an individual particle on a TEM image. In the case when the particle had an elliptical form, the peripheral length thereof was converted to that of a circle, and the obtained diameter was estimated to be a primary particle diameter.

The polyacrylic acid had a weight average molecular weight of 3,000, and the concentration thereof was adjusted to 0.2% by mass of the total mass of the slurry. Furthermore, the pH was adjusted to 3.5 by adding maleic acid as a pH adjusting agent.

Furthermore, sample Nos. 2 and 3 were prepared in a similar manner to sample No. 1, except that the primary particle diameter of 60% by mass of the particles of the entirety of the colloidal silica was changed as follows.

No. 2: Less than 3 nm

No. 3: More than 10 nm

STI (Shallow Trench Isolation) was produced using each slurry, and the polishing property was examined.

A silicon nitride film was formed on a semiconductor substrate 20 as a CMP stopper film 21 to form STI patterns B as illustrated in FIG. 1A. The width and interval of the STI patterns B are both 1 μm (line/space: 1 μm/1 μm). Furthermore, the depth of the STI patterns B is 200 nm.

As shown in FIG. 1B, a silicon oxide film 22 having a thickness of 280 nm was formed on the CMP stopper film 21 by a high-density plasma CVD process (HDP-CVD) or the like. Next, CMP of the whole surface was conducted to remove the silicon oxide film 22 outside of the STI pattern B as illustrated in FIG. 1C.

In the polishing of the silicon oxide film 22, as illustrated in FIG. 2, a polishing head 13 retaining a semiconductor substrate having a film 14 was contacted at a polishing loading of 200 hPa on a turntable 11 to which a polishing cloth 12 had been attached while the turntable 11 was rotated by a rotation mechanism (not depicted) at 100 rpm. The polishing cloth 12 as used herein is IC1000 (manufactured by Nitta Haas, Inc.). The polishing head 13 was rotated at 102 rpm by a rotation mechanism (not depicted), and a sample as a slurry 15 was fed from a slurry feeding nozzle 16 to the central area of the polishing cloth 12.

By conducting polishing for a predetermined period, the silicon oxide film 22 was embedded inside of the STI patterns B, and the surface of the CMP stopper film 21 was exposed outside of the STI patterns B.

The polishing rates (SiO₂ and SiN), SiO₂/SiN selectivity, planarity and scratch count were evaluated according to the following criteria. The polishing time was determined based on the change in the torque current of a motor for rotating the polishing table. The planarity was obtained by measuring line/space (1 μm/1 μm pattern) by an atomic force microscope (AFM), and the scratch was obtained by measuring line/space (1 μm/1 μm pattern) by a wafer defect inspection apparatus KLA2815 (manufactured by KLA-Tencor Corporation). Specifically, the total number of defects was counted by KLA2815, and 50 defects were observed randomly by SEM to classify the defects. The scratch count was obtained by the following numerical formula.

Scratch count=(scratch count observed by SEM)/50×total number of defects

### SiO₂ Polishing Rate

A: 180 nm/min or more

B: 150 nm/min or more and less than 180 nm/min

C: Less than 150 nm/min

### SiN Polishing Rate

A: Less than 10 nm/min

B: 10 nm/min or more and less than 20 nm/min

C: 20 nm/min or more

### SiO₂/SiN Selectivity

A: 15 or more

B: 10 or more and less than 15

C: Less than 10

### Planarity

A: Less than 20 nm

B: 20 nm or more and less than 30 nm

C: 30 nm or more

### Scratch

A: Less than 10

B: 10 or more and less than 30

C: 30 or more

For either evaluation, “C” means NG. It is deemed to be OK when the processing accuracy such as the planarity and scratch are evaluated as “A”, even the SiO₂/SiN selectivity is “B”. The results using the slurries of sample Nos. 1 to 3 are summarized in the following Table 1.

TABLE 1

| | Polishing rate | | | | |
|---|---|---|---|---|---|
| | (nm/min) | | SiO₂/SiN | Planarity | Scratch count |
| No. | SiO₂ | SiN | selectivity | (nm) | (scratches) |
| 1 | A | A | A | A | A |
| 2 | C | A | A | B | B |
| 3 | A | C | C | C | B |

As shown in the Table 1 above, in the case when the particles of 60% by mass of the entirety of the silica each has a primary particle diameter of less than 3 nm (No. 2), the silicon oxide film cannot be polished at a practical rate. Furthermore, the planarity of the surface after the polishing is deteriorated, and the scratch count is increased. On the other hand, in the case when the particles of 60% by mass of the entirety of the silica each has a primary particle diameter of more than 10 nm (No. 3), the polishing cannot be stopped by the silicon nitride film, and a selectivity cannot be obtained. The planarity is further decreased, and the scratch count is increased.

In the case when particles each having a primary particle diameter of 3 to 10 nm account for 60% by mass of the entirety of the silica, all of the conditions of polishing rates (SiO₂ and SiN), selectivity, planarity and scratch count can be satisfied.

Next, sample Nos. 4 to 28 were prepared according to a similar formulation to that of sample No. 1, except that the following points were changed.

By changing the concentration of the silica having a primary particle diameter of 3 to 10 nm to 40, 50, 75, 90 and 100% by mass of the entirety of the silica, sample Nos. 4, 5, 6, 7 and 8 were obtained.

STI was manufactured under similar conditions to those mentioned above except that sample Nos. 4 to 8 were used, and the results thereof were investigated. The polishing rates (SiO₂ and SiN), SiO₂/SiN selectivity, planarity and scratch count were evaluated in similar manners to those mentioned above, and are summarized in the following Table 2.

TABLE 2

| | Polishing rate | | | | |
|---|---|---|---|---|---|
| | (nm/min) | | SiO₂/SiN | Planarity | Scratch count |
| No. | SiO₂ | SiN | Selectivity | (nm) | (scratches) |
| 4 | A | B | B | C | B |
| 5 | A | A | A | A | A |
| 6 | A | A | A | A | A |
| 7 | A | A | A | A | A |
| 8 | A | C | C | C | B |

As shown in the Table 2 above, in the case when the silica having a primary particle diameter of 3 to 10 nm is 40% by mass of the entirety of the silica (No. 4), the polishing rate of the silicon nitride film is increased and the SiO₂/SiN selectivity is decreased. Furthermore, the planarity is decreased significantly and the scratch count is increased. In the case when the primary particle diameter of the whole silica is 3 to 10 nm (No. 8), the polishing rate of the silicon nitride film is increased more significantly, and the selectivity is decreased significantly. The planarity is poor, and the scratch count is increased.

In the case when the silica having a primary particle diameter of from 3 to 10 nm accounts for 50 to 90% by mass of the entirety of the silic, all of conditions of polishing rates (SiO₂ and SiN), SiO₂/SiN selectivity, planarity and scratch count can be satisfied.

The silica concentration with respect to the total mass of the slurry was changed to 0.3, 0.5, 1, 3 and 5% by mass, respectively to give sample Nos. 9, 10, 11, 12 and 13.

STI was manufactured under similar conditions to those mentioned above except that sample Nos. 9 to 13 were used, and the results thereof were investigated. The polishing rates (SiO₂ and SiN), SiO₂/SiN selectivity, planarity and scratch count were evaluated in similar manners to those mentioned above, and are summarized in the following Table 3.

TABLE 3

| | Polishing rate | | | | |
|---|---|---|---|---|---|
| | (nm/min) | | SiO₂/SiN | Planarity | Scratch count |
| No. | SiO₂ | SiN | selectivity | (nm) | (scratches) |
| 9 | C | A | A | B | B |
| 10 | B | A | A | B | A |
| 11 | A | A | A | A | A |
| 12 | A | B | A | A | A |
| 13 | A | C | C | C | B |

As shown in the Table 3 above, in the case when the concentration of the silica is 0.3% by mass of the total mass of the slurry (No. 9), the silicon oxide film cannot be polished at a practical rate. On the other hand, in the case when the concentration of the silica is 5% by mass of the total mass of the slurry (No. 13), the polishing cannot be stopped by the silicon nitride film, and the selectivity and planarity are decreased.

In the case when the silica is included by 0.5 to 3% by mass of the total mass of the slurry, all of the conditions of polishing rates (SiO₂ and SiN), SiO₂/SiN selectivity, planarity and scratch count can be satisfied.

The weight average molecular weight of the polyacrylic acid was changed to 100, 500, 10,000 and 20,000, respectively, to give sample Nos. 14, 15, 16 and 17.

STI was manufactured under similar conditions to those mentioned above except that sample Nos. 14 to 17 were used, and the results thereof were investigated. The polishing rates (SiO₂ and SiN), SiO₂/SiN selectivity, planarity and scratch count were evaluated in similar manners to those mentioned above, and are summarized in the following Table 4.

TABLE 4

| | Polishing rate | | | | |
|---|---|---|---|---|---|
| | (nm/min) | | SiO₂/SiN | Planarity | Scratch count |
| No. | SiO₂ | SiN | selectivity | (nm) | (scratches) |
| 14 | A | B | B | C | B |
| 15 | A | A | A | A | A |
| 16 | B | A | A | A | A |
| 17 | C | A | A | B | B |

As shown in the Table 4 above, desired planarity cannot be obtained in the case when the weight average molecular weight of the polyacrylic acid is 100 (No. 14), and the SiO₂ film cannot be polished at a practical rate in the case when the weight average molecular weight is 20,000 (No. 17). Furthermore, the evaluations on the planarity and scratch are lowered.

In the case when the polyacrylic acid that is included by a predetermined amount has a weight average molecular weight of 500 to 10,000, all of the conditions of polishing rates (SiO₂ and SiN), SiO₂/SiN selectivity, planarity and scratch count can be satisfied.

The concentration of the polyacrylic acid with respect to the total mass of the slurry was changed to 0.05, 0.1, 0.5, 1 and 2% by mass, respectively, to give samples Nos. 18, 19, 20, 21 and 22.

STI was manufactured under similar conditions to those mentioned above except that samples Nos. 18 to 22 were used, and the results thereof were investigated. The polishing rates (SiO₂ and SiN), SiO₂/SiN selectivity, planarity and scratch count were evaluated in similar manners to those mentioned above, and are summarized in the following Table 5.

TABLE 5

| | Polishing rate | | | | |
|---|---|---|---|---|---|
| | (nm/min) | | SiO₂/SiN | Planarity | Scratch count |
| No. | SiO₂ | SiN | selectivity | (nm) | (scratches) |
| 18 | A | B | B | C | C |
| 19 | A | B | B | A | A |
| 20 | A | A | A | A | A |
| 21 | A | A | A | A | A |
| 22 | C | A | B | B | A |

As shown in the Table 5 above, in the case when the concentration of the polyacrylic acid is 0.05% by mass of the total mass of the slurry (No. 18), desired planarity cannot be obtained, and the scratch count is increased. In the case when the concentration of the polyacrylic acid is 2% by mass of the total mass of the slurry (No. 22), the silicon oxide film cannot be polished at a practical rate.

In the case when the polyacrylic acid having a predetermined weight average molecular weight is included by 0.1 to 1% by mass of the total mass of the slurry, all of the conditions of polishing rates (SiO₂ and SiN), SiO₂/SiN selectivity, planarity and scratch count can be satisfied.

The pH was changed to 2, 2.5, 3, 4, 4.5 and 5, respectively, to give samples Nos. 23, 24, 25, 26, 27 and 28.

STI was manufactured under similar conditions to those mentioned above except that the thus-obtained sample Nos. 23 to 28 were used, and the results thereof were investigated. The polishing rates (SiO₂ and SiN), SiO₂/SiN selectivity, planarity and scratch count were evaluated in similar manners to those mentioned above, and are summarized in the following Table 6.

TABLE 6

| | Polishing rate | | | | |
|---|---|---|---|---|---|
| | (nm/min) | | SiO₂/SiN | Planarity | Scratch count |
| No. | SiO₂ | SiN | selectivity | (nm) | (scratches) |
| 23 | B | C | A | B | B |
| 24 | B | A | A | A | A |
| 25 | A | A | A | A | A |
| 26 | A | B | B | A | A |
| 27 | A | B | B | A | A |
| 28 | C | C | C | C | B |

As shown in the Table 6 above, in the case when the pH of the slurry is 2 (No. 23), the polishing cannot be stopped by the silicon nitride film. On the other hand, in the case when the pH of the slurry is 5 (No. 28), the silicon oxide film cannot be polished with a desired rate, and the polishing cannot be stopped by the silicon nitride film. Therefore, selectivity cannot be obtained, and the sample is poor in planarity.

In the case when the pH of the slurry is 2.5 to 4.5, all of the conditions of polishing rates (SiO₂ and SiN), SiO₂/SiN selectivity, planarity and scratch count cap be satisfied.

### EXAMPLE 2

STI was manufactured in a similar manner to that of Example 1, except that a polysilicon film having a thickness of 30 nm was used as a CMP stopper film. For polishing a silicon oxide film, slurries of sample. Nos. 29 to 31 were used.
No. 29: Sample No. 1 mentioned above
No. 30: DLS2 (manufactured by Hitachi Chemical Co., Ltd.)
No. 31: SS25 (manufactured by Cabot Corporation)

DLS2 (manufactured by Hitachi Chemical Co., Ltd.) is a general cerium oxide slurry, and SS25 is a general silica slurry.

The silicon oxide film was polished under similar conditions to those of Example 1, and the polishing rates (SiO₂ and Poly Si), SiO₂/Poly Si selectivity, planarity and scratch count were evaluated according to the following criteria.

### SiO₂ Polishing Rate

A: 180 nm/min or more

B: 150 nm/min or more and less than 180 nm/min

C: Less than 150 nm/min

### Poly Si Polishing Rate

A: Less than 10 nm/min

B: 10 nm/min or more and less than 20 nm/min

C: 20 nm/min or more

### SiO₂/Poly Si Selectivity

A: 15 or more

B: 10 or more and less than 15

C: Less than 10

### Planarity

A: Less than 20 nm

B: 20 nm or more and less than 30 nm

C: 30 nm or more

### Scratch

A: Less than 10

B: 10 or more and less than 30

C: 30 or more

For either evaluation, “C” means NG. It is deemed to be OK when the processing accuracy such as the planarity and scratch are evaluated as “A”, even the

SiO₂/Poly Si selectivity is “B”. The results using the slurries of sample Nos. 29 to 31 are summarized in the following Table 7.

TABLE 7

| | Polishing rate | | | | |
|---|---|---|---|---|---|
| | (nm/min) | | SiO₂/Poly Si | Planarity | Scratch count |
| No. | SiO₂ | Poly Si | selectivity | (nm) | (scratches) |
| 29 | A | A | A | A | A |
| 30 | A | A | A | A | C |
| 31 | A | C | C | C | C |

As shown in the Table 7 above, in the case of the general silica slurry (No. 31), the polishing cannot be stopped by the polysilicon film. On the other hand, in the case of the general ceria slurry (No. 30), the polishing rates (SiO₂ and Poly Si), SiO₂/Poly Si selectivity and planarity are highly evaluated, but scratch cannot be suppressed.

It was confirmed that the slurry of the present example (No. 29) can selectively polish the silicon oxide film formed on the polysilicon film at a practical rate without generating scratch.

### EXAMPLE 3

Sample No. 32 was prepared by adding 1% by mass of hydrogen peroxide to sample No. 1, and sample No. 33 was prepared by adding 1% by mass of ammonium persulfate to sample No. 1.

Furthermore, 1% by mass of hydrogen peroxide was added to W7203 (pH 2.5, manufactured by Cabot Corporation) to give sample No. 34, and 1% by mass of hydrogen peroxide was added to W7573A (pH 2.5, manufactured by Cabot Corporation) to give sample No. 35. W7203 and W7573A are general slurries that are used for touch-up CMP.

Touch-up CMP in the formation of a plug was conducted by using each slurry, and the polishing property was examined.

A silicon oxide film having a thickness of 300 nm was formed as an insulating film 31 on a semiconductor substrate 30, and a silicon nitride film having a thickness of 20 nm was formed thereon as a CMP stopper film 32. As illustrated in FIG. 3A, a hole A is formed on the CMP stopper film 32 and insulating film 31. The hole A was a fine hole having a width of 50 nm and a surface coverage of 50%.

A barrier metal 33 was formed by depositing a TiN film having a thickness of 5 nm on the whole surface by a CVD process, and a wiring material film 34 was formed on the barrier metal 33 by depositing a W film having a thickness of 300 nm by a CVD process.

CMP of the whole surface was conducted using a mixed liquid of ferric nitrate (5 wt %) and fumed alumina (1 wt %) as a slurry to remove the wiring material film 34 outside of the hole A as shown in FIG. 3B (first polish). The wiring material film 34 was embedded in the hole A by the first polish, and the surface of the barrier metal 33 was exposed outside of the hole A.

Thereafter touch-up CMP was conducted to remove the barrier metal 33 outside of the hole A, thereby exposing the surface of the CMP stopper film 32 as illustrated in FIG. 3C. At that time, a part of the surface of the CMP stopper film 32 was also removed. By this way, the wiring material film 34 composed of the W film was embedded in the hole A of the insulating film 31 having the CMP stopper film 32 on the surface thereof through the barrier metal 33 composed of the TiN film, thereby forming a plug.

The touch-up CMP was conducted under similar conditions to those of Example 1. The polishing time was set in view of plane uniformity, and was a time that was 1.3 times longer than the time required for complete removal of the barrier metal 33.

The polishing rates (W, TiN and SiN), W/SiN selectivity, planarity and scratch count were evaluated according to the following criteria. The planarity was obtained by measuring 2 mm of the area of hole width/space (50 nm/50 nm) by AFM. The scratch was obtained by measuring 2 mm of the area of hole width/space (50 nm/50 nm) by KLA.

W polishing Rate

A: 40 nm/min or more

B: 20 nm/min or more and less than 40 nm/min

C: Less than 20 nm/min

### TiN Polishing Rate

A: 40 nm/min or more

B: 20 nm/min or more and less than 40 nm/min

C: Less than 20 nm/min

### SiN Polishing Rate

A: Less than 10 nm/min

B: 10 nm/min or more and less than 20 nm/min

C: 20 nm/min or more

### W/SiN Selectivity

A: 4 or more

B: 2 or more and less than 4

C: Less than 2

### Planarity

A: Less than 20 nm

B: 20 nm or more and less than 30 nm

C: 30 nm or more

### Scratch

A: Less than 10

B: 10 or more and less than 30

C: 30 or more

For either evaluation, “C” means NG. It is deemed to be OK when the processing accuracy such as the planarity and scratch are evaluated as “A”, even the W/SiN selectivity is “B”. The results using the slurries of samples Nos. 32 to 35 are summarized in the following Table 8.

TABLE 8

| | Polishing rate | | | | | |
|---|---|---|---|---|---|---|
| | (nm/min) | | | W/SiN | Planarity | Scratch count |
| No. | W | TiN | SiN | selectivity | (nm) | (scratches) |
| 32 | A | A | A | A | A | A |
| 33 | A | A | A | A | A | A |
| 34 | A | A | C | C | C | B |
| 35 | A | A | C | C | C | C |

As shown in the Table 8 above, the polishing rate of the metal film such as the W film and TiN film is high in the case when either sample is used. In the cases of the commercial products to which the oxidizing agent has been added (Nos. 34 and 35), the polishing rate is high not only against the W film but also against the SiN film, and thus polishing cannot be stopped by the SiN film. As a result, the selectivity and planarity are decreased, and many scratches are generated. On the other hand, in the cases when the slurry sample of the present exemplary embodiment is used (Nos. 32 and 33), all of the conditions of W/SiN selectivity, planarity and scratch count besides polishing rate can be satisfied.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A CMP slurry comprising:
abrasive particles made of colloidal silica in an amount of 0.5 to 3% by mass of a total mass of the CMP slurry, 50 to 90% by mass of the abrasive particles each having a primary particle diameter of 3 to 10 nm; and
a polycarboxylic acid having a weight average molecular weight of 500 to 10,000, in an amount of 0.1 to 1% by mass of the total mass of the CMP slurry, the CMP slurry having a pH within a range of 2.5 to 4.5.

2. The CMP slurry according to claim 1, wherein the abrasive particles account for 1 to 2% by mass of the total mass of the CMP slurry.

3. The CMP slurry according to claim 1, wherein 1% by mass or less of the abrasive particles each has a primary particle diameter of more than 50 nm.

4. The CMP slurry according to claim 1, wherein 10% by mass or less of the abrasive particles each has a primary particle diameter of less than 3 nm.

5. The CMP slurry according to claim 1, wherein the polycarboxylic acid has a weight average molecular weight of 1,000 to 6,000.

6. The CMP slurry according to claim 1, wherein the polycarboxylic acid accounts for 0.3 to 0.6% by mass of the total mass of the CMP slurry.

7. The CMP slurry according to claim 1, wherein the polycarboxylic acid is selected from the group consisting of a polyacrylic acid, a polymethacrylic acid, a polymaleic acid and salts thereof.

8. The CMP slurry according to claim 1, further comprising a pH adjusting agent.

9. The CMP slurry according to claim 8, wherein the pH adjusting agent is selected from the group consisting of maleic acid, citric acid, malic acid, oxalic acid and malonic acid.

10. The CMP slurry according to claim 1, wherein the CMP slurry has a pH of from 3 to 3.5.

11. The CMP slurry according to claim 1, further comprising a nonionic surfactant.

12. The CMP slurry according to claim 11, wherein the nonionic surfactant is selected from the group consisting of polyvinyl alcohol, polyoxyethylene and polyvinyl pyrrolidone.

13. The CMP slurry according to claim 11, wherein the nonionic surfactant accounts for 0.01 to 0.5% by mass of the total mass of the CMP slurry.

14. The CMP slurry according to claim 1, further comprising an oxidizing agent.

15. The CMP slurry according to claim 14, wherein the oxidizing agent is selected from the group consisting of hydrogen peroxide and diammonium persulfate.

16. The CMP slurry according to claim 15, wherein the oxidizing agent accounts for 0.05 to 5% by mass of the total mass of the CMP slurry.

17. A method for manufacturing a semiconductor device comprising:
forming a recess in a semiconductor substrate having a CMP stopper film, through the CMP stopper film;
forming a silicon oxide film in the recess and on the CMP stopper film; and
removing the silicon oxide film on the CMP stopper film by CMP using a CMP slurry according to claim 1 to expose the CMP stopper film.

18. The method according to claim 17, wherein the. CMP stopper film is a silicon nitride film or a polysilicon film.

19. A method for manufacturing a semiconductor device, comprising:
forming a recess in a semiconductor substrate having a CMP stopper film, through the CMP stopper film;
forming a metal film in the recess and on the CMP stopper film; and
removing the metal film on the CMP stopper film by CMP using a CMP slurry according to claim 14 to expose the CMP stopper film.

20. The method according to claim 19, wherein the CMP stopper film is a silicon nitride film or a polysilicon film.
